(19) United States
(12) Patent Application Publication
(10) Pub. No.: US 2026/0324305 A1
(43) Pub. Date: Oct. 15, 2026

(54) SUBSTRATE PROCESSING APPARATUS AND SUBSTRATE PROCESSING METHOD

(71) Applicant: Tokyo Electron Limited, Tokyo (JP)

(72) Inventors: Hideyuki FUKUSHIMA, Koshi City, Kumamoto (JP); Norifumi KOHAMA, Koshi City, Kumamoto (JP)

(73) Assignee: Tokyo Electron Limited, Tokyo (JP)

(21) Appl. No.: 19/106,512

(22) PCT Filed: Aug. 15, 2023
(86) PCT No.: PCT/JP2023/029499

§ 371 Date: Feb. 25, 2025

(30) Foreign Application Priority Data
Aug. 26, 2022 (JP) 2022-135106

(51) Int. Cl. H10P 10/00; H10P 72/00; H10P 72/78

(52) U.S. Cl. CPC H10P 10/128; H10P 72/0428; H10P 72/0616; H10P 72/78

(57) ABSTRACT

A substrate processing apparatus controls a controller to select a periphery-to-center pattern in which an attracting pressure is generated in an order of an outer first zone and a central region, or a center-to-periphery pattern in which the attracting pressure is generated in an order of the central region and the outer first zone, depending on a state of bending of a substrate.

### TECHNICAL FIELD

The various aspects and embodiments described herein pertain generally to a substrate processing apparatus and a substrate processing method.

### BACKGROUND

Patent Document 1 discloses a bonding apparatus that has an upper chuck configured to attract a substrate on the upper side from above and a lower chuck configured to attract a substrate on the lower side from below, and bonds the two substrates facing each other. In the bonding of the substrates, the bonding apparatus presses a central portion of the substrate of the upper chuck to bring it into contact with a central portion of the substrate of the lower chuck, and bonds the central portions of the two substrates together by a molecular force, allowing a bonding region to expand from the central portions to peripheral portions of the substrates.

A substrate processing apparatus configured to attract and hold the substrate as described above may have a risk that it may perform a substrate processing in the state that a residual stress of the substrate is high due to reasons such as bending of the substrate, etc., when the substrate is simply attracted to the chuck.

### PRIOR ART DOCUMENT

Patent Document 1: Japanese Patent-Laid open Publication No. 2015-095579

### DISCLOSURE OF THE INVENTION

### Problems to be Solved by the Invention

Exemplary embodiments provide a technique capable of improving a distribution of a residual stress of a substrate to attract the substrate appropriately.

### Means for Solving the Problems

In an exemplary embodiment, a substrate processing apparatus includes a holder having an attraction surface configured to attract a substrate, the attraction surface having a circular central region and an annular outer region disposed outside the central region; an attracting pressure generator configured to generate an attracting pressure individually in the central region, in an outer first zone set on a portion of the outer region in a circumferential direction, and in an outer second zone set on a portion of the outer region in the circumferential direction, the outer second zone being different from the outer first zone; and a controller configured to control the attracting pressure generator. The controller selects a periphery-to-center pattern in which the attracting pressure is generated in an order of the outer first zone and the central region, or a center-to-periphery pattern in which the attracting pressure is generated in an order of the central region and the outer first zone, depending on a state of bending of the substrate.

### Effect of the Invention

According to the exemplary embodiment, it is possible to improve the distribution of the residual stress of the substrate to attract the substrate appropriately.

### BRIEF DESCRIPTION OF THE DRAWINGS

FIG. 1 is a plan view illustrating a bonding apparatus according to an exemplary embodiment of the present disclosure.

FIG. 2 is a side view of the bonding apparatus of FIG. 1.

FIG. 3 is a side view illustrating an example of a first substrate and a second substrate.

FIG. 4 is a flowchart showing a bonding method of the bonding apparatus.

FIG. 5 is a plan view illustrating an example of a bonding module according to a first exemplary embodiment.

FIG. 6 is a side view of the bonding module of FIG. 5.

FIG. 7 is a cross sectional view illustrating an example of an upper chuck and a lower chuck.

FIG. 8 is a flowchart showing details of a process S109 of FIG. 4.

FIG. 9A is a side view illustrating an example of an operation in a process S112 of FIG. 8,

FIG. 9B is a side view illustrating an operation following that of FIG. 9A, and FIG. 9C is a side view illustrating an operation following that of FIG. 9B.

FIG. 10A is a cross sectional view illustrating an example of an operation in a process S113 of FIG. 8, FIG. 10B is a cross sectional view illustrating an example of an operation in a process S114 of FIG. 8, and FIG. 10C is a cross sectional view illustrating an operation following that of FIG. 10B.

FIG. 11 is a plan view illustrating an example of an attraction surface of the lower chuck.

FIG. 12A is a perspective view illustrating an example of bending of a lower wafer, FIG. 12B is an explanatory diagram illustrating a relationship between the attraction surface and the lower wafer in the Y-axis direction, and FIG. 12C is an explanatory diagram illustrating a relationship between the attraction surface and the lower wafer in the X-axis direction.

FIG. 13 is an explanatory diagram illustrating a relationship between the bending of the lower wafer in the X-axis direction and the bending of the lower wafer in the Y-axis direction.

FIG. 14A is a plan view illustrating an example of an attracting operation for the lower wafer, FIG. 14B is a plan view illustrating an operation following that of FIG. 14A, FIG. 14C is a plan view illustrating an operation following that of FIG. 14B, FIG. 14D is a plan view illustrating an operation following that of FIG. 14C, FIG. 14E is a plan view illustrating an operation following that of FIG. 14D, and FIG. 14F is a plan view illustrating an operation following that of FIG. 14E.

FIG. 15 presents a table illustrating an example of an attracting operation according to bending of the lower wafer.

FIG. 16 is a side view of a bonding module according to a second exemplary embodiment.

FIG. 17 is an explanatory diagram illustrating a relationship between bending of the lower wafer in the X-axis direction, bending of the lower wafer in the Y-axis direction, and a curved surface of the attraction surface.

### DETAILED DESCRIPTION

Hereinafter, exemplary embodiments of the present disclosure will be described with reference to the accompanying drawings. In the various drawings, like parts will be assigned like reference numerals, and redundant descriptions thereof will be omitted.

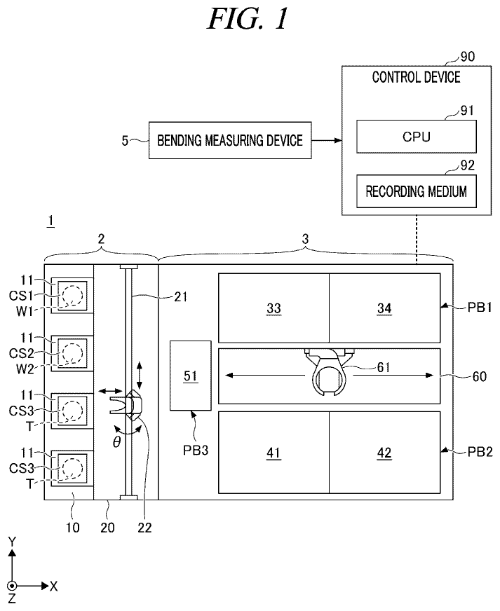

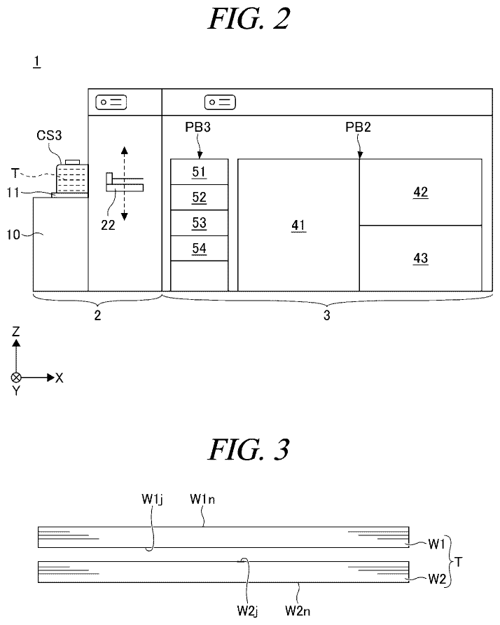

As a substrate processing apparatus of the present disclosure, a bonding apparatus 1 shown in FIG. 1 and FIG. 2 will be representatively described. However, it should be noted that the substrate processing apparatus of the present disclosure is not limited to the bonding apparatus 1 as along as it has a holder for holding a substrate and is configured to process the substrate held by holder. Examples of other substrate processing apparatuses include an exposure device, a temperature adjusting device, and so forth. The exposure device is a device that holds the substrate by the holder and transfers a mask pattern onto the substrate. The temperature adjusting device is a device that holds the substrate by the holder and controls the temperature of the substrate.

The bonding apparatus 1 bonds a first substrate W1 and a second substrate W2 to produce a bonded substrate T, as shown in FIG. 3. At least one of the first substrate W1 and the second substrate W2 is a semiconductor substrate such as, but not limited to, a silicon wafer or a compound semiconductor wafer on which a plurality of electronic circuits are formed. One of the first substrate W1 and the second substrate W2 may be a bare wafer on which no electronic circuit is formed. Although the compound semiconductor wafer is not particularly limited, it may be, by way of example, a GaAs wafer, a SIC wafer, a GaN wafer, or an InP wafer.

The first substrate W1 and the second substrate W2 are formed as circular plates having approximately the same shape (same diameter). The bonding apparatus 1 bonds the first substrate W1 and the second substrate W2 after placing the second substrate W2 on the negative Z-axis side of (vertically under) the first substrate W1. Therefore, hereinafter, the first substrate W1 may sometimes be referred to as “upper wafer W1,” the second substrate W2 may sometimes be referred to as “lower wafer W2,” and the bonded substrate T may sometimes be referred to as the “bonded wafer T.” In addition, hereinafter, among plate surfaces of the upper wafer W1, the plate surface to be bonded to the lower wafer W2 will be referred to as “bonding surface W1j,” and the plate surface opposite to the bonding surface W1j will be referred to as “non-bonding surface W1n.” Likewise, among plate surfaces of the lower wafer W2, the plate surface to be bonded to the upper wafer W1 will be referred to as “bonding surface W2j”, and the plate surface opposite to the bonding surface W2j will be referred to as “non-bonding surface W2n”.

As shown in FIG. 1, the bonding apparatus 1 includes a carry-in/out station 2 and a processing station 3 arranged in this order in the positive X-axis direction. The carry-in/out station 2 and the processing station 3 are connected as one body.

The carry-in/out station 2 includes a placement table 10 and a transfer section 20. The placement table 10 is equipped with a multiple number of placement plates 11. Respectively provided on the placement plates 11 are cassettes CS1, CS2, and CS3 each of which accommodates therein a plurality of (e.g., 25 sheets of) substrates horizontally. The cassette CS1 accommodates therein upper wafers W1; the cassette CS2, lower wafers W2; and the cassette CS3, bonded wafers T. In the cassettes CS1 and CS2, the upper wafers W1 and the lower wafers W2 are accommodated in the same direction with their bonding surfaces W1j and Wj2 facing upwards, respectively.

The transfer section 20 is provided adjacent to the positive X-axis side of the placement table 10, and is equipped with a transfer path 21 extending in the Y-axis direction and a transfer device 22 configured to be movable along the transfer path 21. The transfer device 22 is configured to be movable in the X-axis direction as well as in the Y-axis direction and pivotable around the Z-axis, and serves to transfer the upper wafers W1, the lower wafers W2, and the bonded wafers T between the cassettes CS1 to CS3 placed on the placement table 10 and a third processing block PB3 of the processing station 3 to be described later.

The processing station 3 is provided with, for example, three processing blocks PB1, PB2, and PB3. The first processing block PB1 is disposed on the rear side of the processing station 3 (positive Y-axis side of FIG. 1). Further, the second processing block PB2 is provided on the front side of the processing station 3 (negative Y-axis side of FIG. 1), and the third processing block PB3 is disposed on the carry-in/out station 2 side of the processing station 3 (negative X-axis side of FIG. 1).

Further, the processing station 3 is equipped with a transfer section 60 having a transfer device 61 in a region surrounded by the first to third processing blocks PB1 to PB3. For example, the transfer device 61 has a transfer arm configured to be movable in a vertical direction and a horizontal direction and pivotable around a vertical axis. This transfer device 61 is moved within the transfer section 60 and transfers the upper wafers W1, the lower wafers W2 and the bonded wafers T to apparatuses within the first to third processing blocks PB1 to PB3 which are adjacent to the transfer section 60.

The first processing block PB1 has, by way of example, a surface modifying apparatus 33 and a surface hydrophilizing apparatus 34. The surface modifying apparatus 33 is configured to modify the bonding surface W1j of the upper wafer W1 and the bonding surface W2j of the lower wafer W2. The surface hydrophilizing apparatus 34 is configured to hydrophilize the modified bonding surfaces W1j and W2j of the upper and lower wafers W1 and W2.

For example, the surface modifying apparatus 33 cuts a SiO2 bond on the bonding surfaces W1j and W2j to form a dangling bond of Si, thus allowing the bonding surfaces W1j and W2j to be hydrophilized afterwards. In the surface modifying apparatus 33, an oxygen gas as a processing gas is excited into plasma to be ionized under a decompressed atmosphere, for example. As oxygen ions are radiated to the bonding surface W1j of the upper wafer W1 and the bonding surface W2j of the lower wafer W2, the bonding surfaces W1j and W2j are plasma-processed to be modified. The processing gas is not limited to the oxygen gas, but it may be a nitrogen gas or the like.

The surface hydrophilizing apparatus 34 is configured to hydrophilize the bonding surface W1j of the upper wafer W1 and the bonding surface W2j of the lower wafer W2 with a hydrophilizing liquid such as pure water. The surface hydrophilizing apparatus 34 also has a function of cleaning the bonding surfaces W1j and W2j. In the surface hydrophilizing apparatus 34, while rotating the upper wafer W1 or the lower wafer W2 held by, for example, a spin chuck, the pure water is supplied onto the upper wafer W1 or the lower wafer W2. Accordingly, the pure water is diffused on the bonding surfaces W1j and W2j, and an OH group is attached to the dangling bond of Si, so that the bonding surfaces W1j and W2j are hydrophilized.

As shown in FIG. 2, the second processing block PB2 includes, for example, a bonding module 41, a first temperature adjusting device 42, and a second temperature adjusting device 43. The bonding module 41 is configured to bond the hydrophilized upper wafer W1 and lower wafer W2 to produce the bonded wafer T. The first temperature adjusting device 42 is configured to adjust a temperature distribution of the upper wafer W1 before producing the bonded wafer T. The second temperature adjusting device 43 is configured to adjust a temperature distribution of the lower wafer W2 before producing the bonded wafer T. In addition, in the present exemplary embodiment, although the first temperature adjusting device 42 and the second temperature adjusting device 43 are provided separately from the bonding module 41, they may be provided as a part of the bonding module 41.

The third processing block PB3 is equipped with a first position adjusting device 51, a second position adjusting device 52, and transition devices 53 and 54 in this order from top to bottom, for example. Further, the places where the individual devices are disposed in the third processing block PB3 are not limited to the example shown in FIG. 2. The first position adjusting device 51 is configured to adjust the direction of the upper wafer W1 in a horizontal direction, and invert the upper wafer W1 upside down so that the bonding surface W1j of the upper wafer W1 faces downwards. The second position adjusting device 52 is configured to adjust the direction of the lower wafer W2 in the horizontal direction. The transition device 53 is configured to temporarily place therein the upper wafer W1. Further, the transition device 54 is configured to temporarily place therein the lower wafer W2 and the bonded wafer T.

Referring back to FIG. 1, the bonding apparatus 1 is equipped with a control device (controller) 90 configured to control the individual components. The control device 90 is a control computer having one or more processors 91, a memory 92, a non-illustrated input/output interface, and an electronic circuit. The one or more processors 91 are implemented by one of a CPU (Central Processing Unit), an ASIC (Application Specific Integrated Circuit), an FPGA (Field-Programmable Gate Array), and a circuit composed of a plurality of discrete semiconductors, or a combination thereof, and are configured to execute programs stored in the memory 92. The memory 92 includes a nonvolatile memory and a volatile memory, and constitutes a storage of the control device 90.

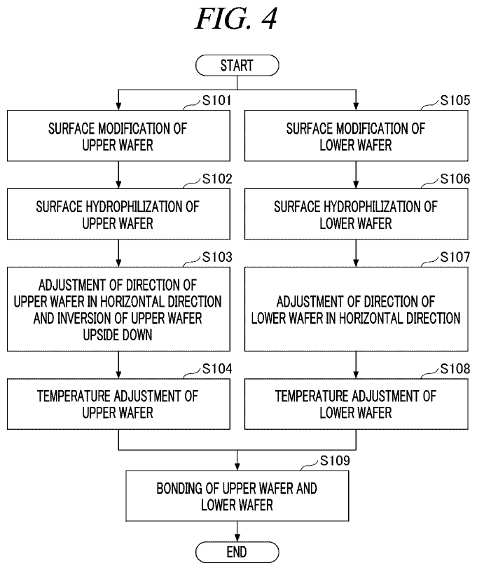

Now, referring to FIG. 4, a bonding method according to the present exemplary embodiment will be described. Processes S101 to S109 shown in FIG. 4 are performed under the control of the control device 90.

In the bonding method, a worker or a transfer robot (not shown) places the cassette CS1 accommodating the plurality of upper wafers W1, the cassette CS2 accommodating the plurality of lower wafers W2, and the empty cassette CS3 on the placement table 10 of the carry-in/out station 2.

The bonding apparatus 1 takes out the upper wafer W1 within the cassette CS1 by the transfer device 22, and transfers it to the transition device 53 of the third processing block PB3 of the processing station 3. Thereafter, the bonding apparatus 1 takes out the upper wafer W1 from the transition device 53 by the transfer device 61, and transfers it to the surface modifying apparatus 33 of the first processing block PB1.

Then, the bonding apparatus 1 modifies the bonding surface W1j of the upper wafer W1 by the surface modifying apparatus 33 (process S101). The surface modifying apparatus 33 modifies the bonding surface W1j while allowing the bonding surface W1j to face upwards. Thereafter, the transfer device 61 takes out the upper wafer W1 from the surface modifying apparatus 33, and transfers it to the surface hydrophilizing apparatus 34.

Then, the bonding apparatus 1 hydrophilizes the bonding surface W1j of the upper wafer W1 by the surface hydrophilizing apparatus 34 (process S102). The surface hydrophilizing apparatus 34 hydrophilizes the bonding surface W1j while allowing the bonding surface W1j to face upwards. Thereafter, the transfer device 61 takes out the upper wafer W1 from the surface hydrophilizing apparatus 34, and transfers it to the first position adjusting device 51 of the third processing block BP3.

The bonding apparatus 1 adjusts the direction of the upper wafer W1 in the horizontal direction by the first position adjusting device 51, and also turns the upper wafer W1 up and down (process S103). As a result, a notch of the upper wafer W1 is directed toward a predetermined direction, and the bonding surface W1j of the upper wafer W1 is turned downwards. Thereafter, the transfer device 61 takes out the upper wafer W1 from the first position adjusting device 51, and transfers it to the first temperature adjusting device 42 of the second processing block BP2.

The bonding apparatus 1 controls the temperature of the upper wafer W1 by the first temperature adjusting device 42 (process S104). The temperature adjustment of the upper wafer W1 is performed with its bonding surface W1j facing downwards. Thereafter, the transfer device 61 takes out the upper wafer W1 from the first temperature adjusting device 42, and transfers it to the bonding module 41.

The bonding apparatus 1 performs a processing on the lower wafer W2 in parallel with the above-described processing on the upper wafer W1. First, the bonding apparatus 1 takes out the lower wafer W2 within the cassette CS2 by the transfer device 22, and transfers it to the transition device 54 of the third processing block BP3 of the processing station 3. Thereafter, the transfer device 61 takes out the lower wafer W2 from the transition device 54, and transfers it to the surface modifying apparatus 33 of the first processing block BP1.

The bonding apparatus 1 modifies the bonding surface W2j of the lower wafer W2 by the surface modifying apparatus 33 (process S105). The surface modifying apparatus 33 modifies the bonding surface W2j while allowing the bonding surface W2j to face upwards. Thereafter, the transfer device 61 takes out the lower wafer W2 from the surface modifying apparatus 33, and transfers it to the surface hydrophilizing apparatus 34.

The bonding apparatus 1 hydrophilizes the bonding surface W2j of the lower wafer W2 by the surface hydrophilizing apparatus 34 (process S106). The surface hydrophilizing apparatus 34 hydrophilizes the bonding surface W2j while allowing the bonding surface W2j to face upwards. Thereafter, the transfer device 61 takes out the lower wafer W2 from the surface hydrophilizing apparatus 34, and transfers it to the second position adjusting device 52 of the third processing block BP3.

The bonding apparatus 1 adjusts the direction of the lower wafer W2 in the horizontal direction by the second position adjusting device 52 (process S107). As a result, a notch of the lower wafer W2 is directed toward a preset direction. Thereafter, the transfer device 61 takes out the lower wafer W2 from the second position adjusting device 52, and transfers it to the second temperature adjusting device 43 of the second processing block BP2.

The bonding apparatus 1 adjusts the temperature of the lower wafer W2 by the second temperature adjusting device 43 (process S108). The temperature adjustment of the lower wafer W2 is performed with its bonding surface W2j facing upwards. Thereafter, the transfer device 61 takes out the lower wafer W2 from the second temperature adjusting device 43, and transfers it to the bonding module 41.

Then, the bonding apparatus 1 bonds the upper wafer W1 and the lower wafer W2 in the bonding module 41 to produce the bonded wafer T (process S109). After the production of the bonded wafer T, the transfer device 61 takes out the bonded wafer T from the bonding module 41, and transfers it to the transition device 54 of the third processing block BP3.

Finally, the bonding apparatus 1 takes out the bonded wafer T from the transition device 54 by the transfer device 22, and transfers it to the cassette CS3 on the placement table 10. In this way, the series of processes are completed.

### First Exemplary Embodiment

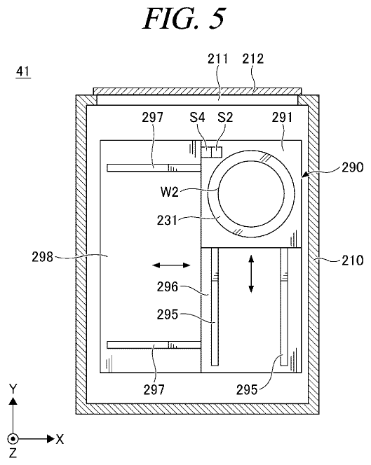

Now, referring to FIG. 5 to FIG. 7, an example of the bonding module 41 according to a first exemplary embodiment will be described. As illustrated in FIG. 5, the bonding module 41 has a processing vessel 210 whose inside is hermetically sealable. A carry-in/out opening 211 is formed in a side surface of the processing vessel 210 on the transfer section 60 side, and an opening/closing shutter 212 is provided at the carry-in/out opening 211. The upper wafer W1, the lower wafer W2, and the bonded wafer T are carried in or out through the carry-in/out opening 211.

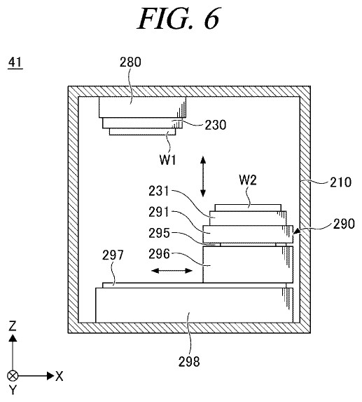

As depicted in FIG. 6, an upper chuck 230 and a lower chuck 231 are provided inside the processing vessel 210. The upper chuck 230 holds the upper wafer W1 from above, allowing the bonding surface W1j of the upper wafer W1 to face downwards. Further, the lower chuck 231 is provided below the upper chuck 230, and holds the lower wafer W2 from below, allowing the bonding surface W2j of the lower wafer W2 to face upwards.

The upper chuck 230 is supported by a supporting member 280 provided on a ceiling surface of the processing vessel 210. Meanwhile, the lower chuck 231 is supported by a first lower chuck mover 291 provided below the lower chuck 231.

The first lower chuck mover 291 moves the lower chuck 231 in a horizontal direction (Y-axis direction) as will be described later. In addition, the first lower chuck mover 291 is configured to be capable of moving the lower chuck 231 in a vertical direction and rotating it around a vertical axis.

The first lower chuck mover 291 is mounted to a pair of rails 295 provided on a bottom surface side of the first lower chuck mover 291 and extending in the horizontal direction (Y-axis direction). The first lower chuck mover 291 is configured to be movable along the rails 295. The rails 295 are provided on a second lower chuck mover 296.

The second lower chuck mover 296 is mounted to a pair of rails 297 provided on a bottom surface side of the second lower chuck mover 296 and extending in a horizontal direction (X-axis direction). The second lower chuck mover 296 is configured to be movable along the rails 297. In addition, the pair of rails 297 are disposed on a placement table 298 which is provided on a bottom surface of the processing vessel 210.

The first lower chuck mover 291 and the second lower chuck mover 296 constitute a moving mechanism 290. The moving mechanism 290 moves the lower chuck 231 relative to the upper chuck 230. Further, the moving mechanism 290 moves the lower chuck 231 between a substrate delivery position and a bonding position.

The substrate delivery position is a position where the upper chuck 230 receives the upper wafer W1 from the transfer device 61, the lower chuck 231 receives the lower wafer W2 from the transfer device 61, and the lower chuck 231 delivers the bonded wafer T to the transfer device 61. The substrate delivery position is a position where a carry-out of the bonded wafer T produced by the nth (n is a natural number equal to or larger than 1) bonding and a carry-in of the upper wafer W1 and the lower wafer W2 to be bonded by the (n+1)th bonding are performed in succession. The substrate delivery position is, for example, a position shown in FIG. 5 and FIG. 6.

When handing the upper wafer W1 over to the upper chuck 230, the transfer device 61 advances to a space directly under the upper chuck 230. Also, when receiving the bonded wafer T from the lower chuck 231 and handing the lower wafer W2 over to the lower chuck 231, the transfer device 61 advances to a space directly over the lower chuck 231. The upper chuck 230 and the lower chuck 231 are placed sideways apart and a distance between the upper chuck 230 and the lower chuck 231 in a vertical direction is large so that the transfer device 61 advances therebetween easily.

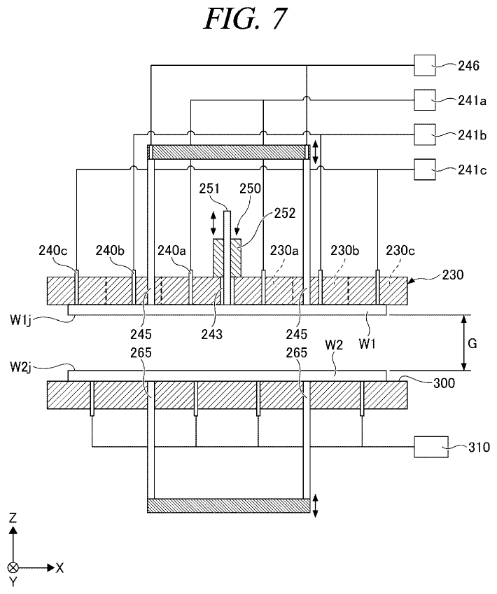

Meanwhile, the bonding position is a position where the upper wafer W1 and the lower wafer W2 are made to face each other with a preset distance therebetween. The bonding 14 position is, for example, a position shown in FIG. 7. At the bonding position, the distance between the upper wafer W1 and the lower wafer W2 in the vertical direction is narrower than that at the substrate delivery position. Further, at the bonding position, the upper wafer W1 and the lower wafer W2 overlap each other when viewed from the vertical direction, unlike at the substrate delivery position.

The moving mechanism 290 moves the relative positions of the upper chuck 230 and the lower chuck 231 in the horizontal directions (both the X-axis direction and the Y-axis direction) and the vertical direction. Although the moving mechanism 290 moves the lower chuck 231 in the present exemplary embodiment, it may move any one of the lower chuck 231 and the upper chuck 230, or both of them. Further, the moving mechanism 290 may rotate the upper chuck 230 or the lower chuck 231 around a vertical axis.

As illustrated in FIG. 7, the upper chuck 230 is divided into a plurality of (for example, three) regions 230a, 230b, and 230c along a diametrical direction of the upper chuck 230. These regions 230a, 230b, and 230c are provided in this order from the center of the upper chuck 230 toward an outer periphery thereof. The region 230a is formed in a circular shape when viewed from the top, and the regions 230b and 230c are formed in an annular shape when viewed from the top.

Suction lines 240a, 240b, and 240c are independently provided in the regions 230a, 230b, and 230c, respectively. Separate vacuum pumps 241a, 241b, and 241c are connected to the suction lines 240a, 240b, and 240c, respectively. The upper chuck 230 is capable of vacuum-attracting the upper wafer W1 in each of the regions 230a, 230b, and 230c individually.

The upper chuck 230 is provided with a multiple number of holding pins 245 configured to be movable up and down in the vertical direction. The plurality of holding pins 245 are connected to a vacuum pump 246, and the upper wafer W1 is vacuum-attracted to the holding pins 245 by the operation of the vacuum pump 246. The upper wafer W1 is vacuum-attracted to lower ends of the multiple number of holding pins 245. Instead of the multiple number of holding pins 245, a ring-shaped attraction pad may be used.

The multiple number of holding pins 245 are protruded from an attraction surface of the upper chuck 230 as they are lowered by a non-illustrated driver. In this state, the holding pins 245 receive the upper wafer W1 from the transfer device 61 by vacuum-attracting it. Thereafter, the multiple number of holding pins 245 are raised, allowing the upper wafer W1 to come into contact with the attraction surface of the upper chuck 230. Then, the upper chuck 230 vacuum-attracts the upper wafer W1 horizontally in the respective regions 230a, 230b, and 230c by the operations of the vacuum pumps 241a, 241b, and 241c, respectively.

In addition, the upper chuck 230 has a through hole 243 which is formed through a central portion of the upper chuck 230 in the vertical direction. A pushing member 250 is inserted through the through hole 243. The pushing member 250 presses the center of the upper wafer W1 spaced apart from the lower wafer W2, thus bringing the upper wafer W1 into contact with the lower wafer W2.

The pushing member 250 has a pushing pin 251 and an outer cylinder 252 serving as an elevation guide for the pushing pin 251. The pushing pin 251 is inserted through the through hole 243 by, for example, a driver (not shown) having a motor therein, and is protruded from the attraction surface of the upper chuck 230, pressing the center of the upper wafer W1.

Further, the lower chuck 231 also has a plurality of divided regions in an attraction surface 300 for attracting the lower wafer W2. The configuration of the attraction surface 300 of the lower chuck 231 will be described in detail later.

The lower chuck 231 is provided with a plurality of (for example, three) holding pins 265 configured to be movable up and down in the vertical direction. The lower wafer W2 is placed on upper ends of the plurality of holding pins 265. Further, the lower wafer W2 may be vacuum-attracted to the upper ends of the plurality of holding pins 265.

The plurality of holding pins 265 are protruded from the attraction surface 300 of the lower chuck 231 as they are raised. In this state, the plurality of holding pins 265 receive the lower wafer W2 from the transfer device 61. Thereafter, the plurality of holding pins 265 are lowered, thus allowing the lower wafer W2 to come into contact with the attraction surface 300 of the lower chuck 231. Subsequently, the lower chuck 231 vacuum-attracts the lower wafer W2 horizontally in the plurality of regions of the attraction surface 300.

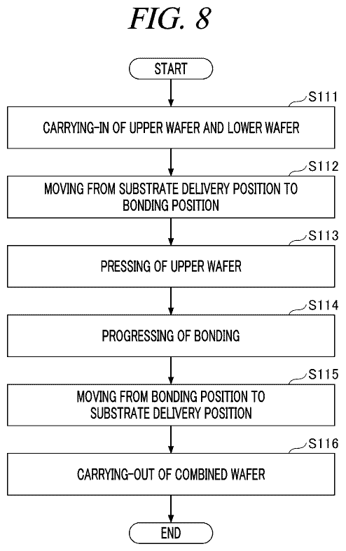

Now, with reference to FIG. 8 to FIG. 10C, the process of producing the bonded wafer T in the process S109 of FIG. 4 will be described in detail. As depicted in FIG. 8, the control device 90 controls the transfer device 61 to carry the upper wafer W1 and the lower wafer W2 into the bonding module 41 (process S111). As for the relative positions of the upper chuck 230 and the lower chuck 231 after being carried in, they are at the substrate delivery position as shown in FIG. 6 and FIG. 7.

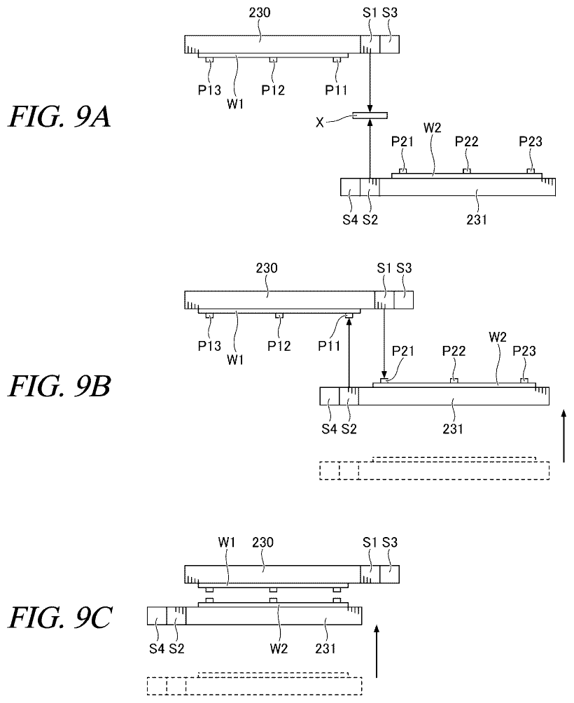

Next, the control device 90 controls the moving mechanism 290 to move the relative positions of the upper chuck 230 and the lower chuck 231 from the substrate delivery position to the bonding position shown in FIG. 7 (process S112). In this process S112, the control device 90 carries out alignment between the upper wafer W1 and the lower wafer W2 by using a first camera S1 and a second camera S2 as shown in FIG. 9A to FIG. 9C.

The first camera S1 is fixed to the upper chuck 230 to image the lower wafer W2 held by the lower chuck 231. Multiple reference points P21 to P23 are previously formed on the bonding surface W2j of the lower wafer W2. As the reference points P21 to P23, patterns of electronic circuits or the like may be used. The number of the reference points is not particularly limited.

Meanwhile, the second camera S2 is fixed to the lower chuck 231 to image the upper wafer W1 held by the upper chuck 230. Multiple reference points P11 to P13 are previously formed on the bonding surface W1j of the upper wafer W1. As the reference points P11 to P13, patterns of electronic circuits or the like may be used. The number of these reference points is not particularly limited.

As depicted in FIG. 9A, the bonding module 41 adjusts the relative positions of first camera S1 and second camera S2 in the horizontal direction by the moving mechanism 290. Specifically, the moving mechanism 290 moves the lower chuck 231 in the horizontal direction such that the second camera S2 is positioned substantially directly below the first camera S1. Then, the first camera S1 and the second camera S2 image a common target X and the moving mechanism 290 finely adjusts the position of the second camera S2 in the horizontal direction such that the positions of the first camera S1 and the second camera S2 in the horizontal direction are coincident.

Subsequently, as shown in FIG. 9B, the moving mechanism 290 moves the lower chuck 231 vertically upwards and adjusts the positions of the upper chuck 230 and the lower chuck 231 in the horizontal direction. Specifically, while the moving mechanism 290 is moving the lower chuck 231 in the horizontal direction, the first camera S1 sequentially images the reference points P21 to P23 of the lower wafer W2, and the second camera S2 sequentially images the reference points P11 to P13 of the upper wafer W1. FIG. 9B shows a state in which the first camera S1 is imaging the reference point P21 of the lower wafer W2 and the second camera S2 is imaging the reference point P11 of the upper wafer W1.

The first camera S1 and the second camera S2 transmit the obtained image data to the control device 90. The control device 90 controls the moving mechanism 290 based on the image data obtained by the first camera S1 and the image data obtained by the second camera S2, and adjusts the position of the lower chuck 231 in the horizontal direction such that the reference points P11 to P13 of the upper wafer W1 and the reference points P21 to P23 of the lower wafer W2 coincide with each other when viewed from the vertical direction.

Thereafter, as illustrated in FIG. 9C, the moving mechanism 290 moves the lower chuck 231 vertically upwards. As a result, a distance G (see FIG. 7) between the bonding surface W2j of the lower wafer W2 and the bonding surface W1j of the upper wafer W1 becomes a predetermined distance of, e.g., 80 μm to 200 μm. The adjustment of the distance G is performed by using a first displacement meter S3 and a second displacement meter S4.

The first displacement meter S3 is fixed to the upper chuck 230, and measures the thickness of the lower wafer W2 held by the lower chuck 231. The first displacement meter S3 measures the thickness of the lower wafer W2 by, for example, radiating light to the lower wafer W2 and receiving reflection light reflected from both top and bottom surfaces of the lower wafer W2. For example, this thickness measurement is performed when the moving mechanism 290 moves the lower chuck 231 in the horizontal direction. The first displacement meter S3 carries out the measurement by, for example, a confocal method, a spectral interference method, or a triangulation method. A light source of the first displacement meter S3 is an LED or a laser.

Meanwhile, the second displacement meter S4 is fixed to the lower chuck 231, and measures the thickness of the upper wafer W1 held by the upper chuck 230. The second displacement meter S4 measures the thickness of the upper wafer W1 by, for example, radiating light to the upper wafer W1 and receiving reflection light reflected from both top and bottom surfaces of the upper wafer W1. For example, this thickness measurement is performed when the moving mechanism 290 moves the lower chuck 231 in the horizontal direction. The second displacement meter S4 carries out the measurement by, for example, a confocal method, a spectral interference method, or a triangulation method. A light source of the second displacement meter S4 is an LED or a laser.

The first displacement meter S3 and the second displacement meter S4 transmit the obtained measurement data to the control device 90. The control device 90 controls the moving mechanism 290 based on the measurement data obtained by the first displacement meter S3 and the measurement data obtained by the second displacement meter S4, and adjusts the position of the lower chuck 231 in the vertical direction such that the distance G becomes the set value.

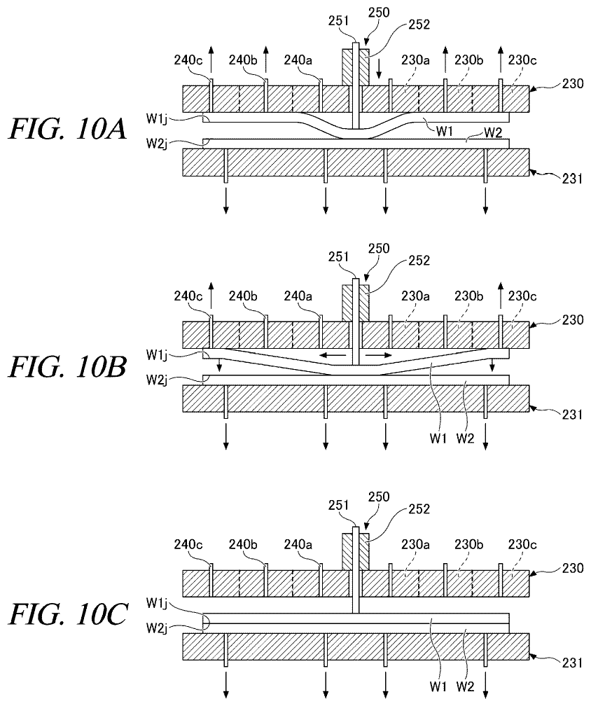

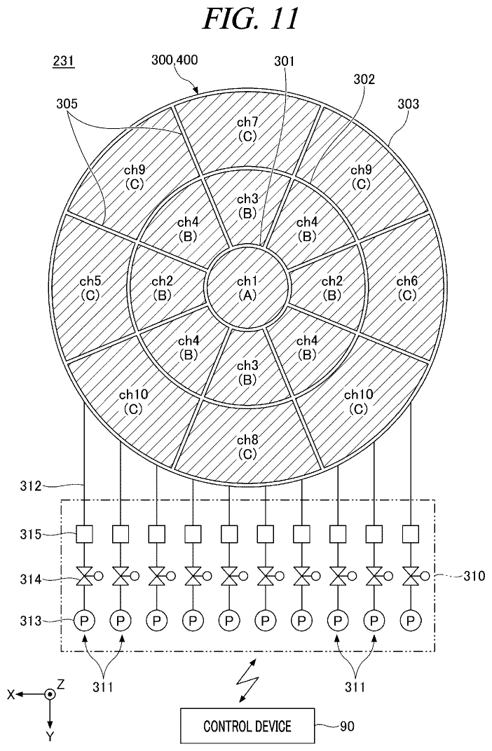

Next, the operation of the vacuum pump 241a is stopped, so that the vacuum attraction of the upper wafer W1 in the region 230a is released, as illustrated in FIG. 10A. Thereafter, the pushing pin 251 of the pushing member 250 is lowered to press the center of the upper wafer W1, allowing the upper wafer W1 to come into contact with the lower wafer W2 (process S113). As a result, the centers of the upper and lower wafers W1 and W2 are bonded to each other.

Since the bonding surface W1j of the upper wafer W1 and the bonding surface W2j of the lower wafer W2 are modified, a van der Waals force (intermolecular force) is first generated between the bonding surfaces W1j and W2j, so that the bonding surfaces W1j and W2j are bonded to each other. Further, since the bonding surface W1j of the upper wafer W1 and the bonding surface W2j of the lower wafer W2 have been hydrophilized, hydrophilic groups (e.g., OH groups) are hydrogen-bonded, allowing the bonding surfaces W1j and W2j to be firmly bonded to each other.

Subsequently, the control device 90 stops the operation of the vacuum pump 241b, and releases the vacuum attraction of the upper wafer W1 in the region 230b, as shown in FIG. 11B. Afterwards, the control device 90 stops the operation of the vacuum pump 241c, and releases the vacuum attraction of the upper wafer W1 in the region 230c, as shown in FIG. 11C.

In this way, the vacuum attraction of the upper wafer W1 is released step by step from the center toward the periphery of the upper wafer W1, so that the upper wafer W1 drops and comes into contact with the lower wafer W2 step by step. Then, the bonding of the upper wafer W1 and the lower wafer W2 proceeds sequentially toward the peripheries of the upper and lower wafers W1 and W2 after the centers thereof are bonded (process S114). As a result, the entire bonding surface W1j of the upper wafer W1 and the entire bonding surface W2j of the lower wafer W2 come into contact with each other, so that the upper wafer W1 and the lower wafer W2 are bonded together, and the bonded wafer T is obtained. Then, the bonding apparatus 1 raises the pushing pin 251 to its original position.

After the bonded wafer T is formed, the control device 90 controls the moving mechanism 290 to move the relative positions of the upper chuck 230 and the lower chuck 231 from the bonding positions shown in FIG. 8 to the substrate delivery positions shown in FIG. 6 and FIG. 7 (process S115). By way of example, the moving mechanism 290 first lowers the lower chuck 231 to widen the distance between the lower chuck 231 and the upper chuck 230 in the vertical direction. Then, the moving mechanism 290 moves the lower chuck 231 sideways so that the lower chuck 231 and the upper chuck 230 are placed sideways apart.

Thereafter, the control device 90 controls the transfer device 61 to carry out the bonded wafer T from the bonding module 41 (process S116). Specifically, the lower chuck 231 first releases the holding of the bonded wafer T. Then, the plurality of holding pins 265 are raised to hand the bonded wafer T over to the transfer device 61. Thereafter, the plurality of holding pins 265 are lowered to their original positions.

Now, the configuration of the attraction surface 300 of the lower chuck 231 will be described with reference to FIG. 11. Further, this technique of the present disclosure is also applicable to the attraction surface of the upper chuck 230. In FIG. 11, hatched regions are regions in which an attracting pressure is generated. The attraction surface 300 of the lower chuck 231 has the plurality of regions that generate the attracting pressure individually.

For example, the attraction surface 300 is partitioned into a central region A, an intermediate region B, and an outer region C by annular ribs 301, 302, and 303. The central region A, the intermediate region B, and the outer region C are arranged concentrically in this order from the center of the attraction surface 300 toward an outer periphery thereof. Specifically, the central region A is formed in a circle shape. The intermediate region B is formed in an annular shape at a position outside and adjacent to the central region A. The outer region C is formed in an annular shape at a position outside and adjacent to the intermediate region B. Alternatively, the attraction surface 300 may not include the intermediate region B, and the outer region C may be positioned outside the central region A to be adjacent thereto. Still alternatively, the attraction surface 300 may include a plurality of annular intermediate regions B between the central region A and the outer region C.

The intermediate region B is divided into eight arc-shaped zones (sub-regions) by a plurality of ribs 305 having a radial pattern. Likewise, the outer region C is also divided into eight 22 arc-shaped zones by the ribs 305. Here, the number of the divisions of the intermediate region B may be equal to or different from the number of the divisions of the outer region C.

The central region A, the eight zones of the intermediate region B, and the eight zones of the outer region C are configured to be capable of suctioning the lower wafer W2 individually. Here, however, in the lower chuck 231 according to the present exemplary embodiment, ten suction mechanisms 311 are connected to the total of seventeen zones, and the attraction surface 300 are suctioned for the zones of ten channels individually. That is, the attraction surface 300 has, among the total of seventeen zones, zones in which the suctioning is performed by the same suction mechanism 311.

To elaborate, a single zone ch1 is set for the central region A, and this zone ch1 is connected to the preset suction mechanism 311. Meanwhile, in the intermediate region B, three different zones ch2 to ch4 are set. Two zones adjacent to each other in the X-axis direction (left-and-right direction in FIG. 11) with the central region A therebetween are the zones ch2. Two zones adjacent to each other in the Y-axis direction (up-and-down direction in FIG. 11) with the central region A therebetween are the zones ch3. Further, four zones interposed between the zones ch2 and the zones ch3 in the intermediate region B are the zones ch4. Meanwhile, in the outer region C, six different zones ch5 to ch10 are set. One zone adjacent to the intermediate region B in the positive X-axis direction (left side in FIG. 11) is the zone ch5. One zone adjacent to the intermediate region B in the negative X-axis direction (right side in FIG. 11) is the zone ch6. One zone adjacent to the intermediate region B in the negative Y-axis direction (upper side in FIG. 11) is the zone ch7. One zone adjacent to the intermediate region B in the positive Y-axis direction (bottom side in FIG. 11) is the zone ch8. Further, the zone interposed between the zone ch5 and the zone ch7 and the zone interposed between the zone ch6 and the zone ch7 in the outer region 23 C are the zones ch9. Likewise, the zone interposed between the zone ch5 and the zone ch8 and the zone interposed between the zone ch6 and the zone ch8 in the outer region C are the zones ch10.

On the X-axis passing through the center of the attraction surface 300, the zones ch5, ch2, ch1, ch2, and ch6 are arranged in this order from the positive X-axis side toward the negative X-axis side. On the Y-axis passing through the center of the attraction surface 300, the zones ch7, ch3, ch1, ch3, and ch8 are arranged in this order from the negative Y-axis side toward the positive Y-axis side. Here, however, it should be noted that the number and the location of the channels of the respective zones of the attraction surface 300 may be designed as required without being particularly limited.

The bonding module 41 is equipped with an attracting pressure generator 310 configured to generate an attracting pressure in the respective zones of the ten channels of the attraction surface 300 individually. The suction mechanisms 311 of the attracting pressure generator 310 have suction lines 312 respectively connected to the predetermined zones, and a suction pump 313, an opening/closing valve 314 and a pressure controller 315 are provided on each of these suction lines 312. The attracting pressure generator 310 is connected to the control device 90 so as to communicate with it, and operates the respective suction mechanisms 311 under the control of the control device 90.

Each suction mechanism 311 opens the opening/closing valve 314 by operating the suction pump 313 of the corresponding suction line 312, thus generating the attracting pressure (negative pressure) in the zone to which that suction line 312 is connected. The magnitude of the attracting pressure is controlled by the pressure controller 315. Further, each suction mechanism 311 releases the attracting pressure of the zone by closing the opening/closing valve 314 of the suction line 312 and introducing air via the pressure controller 315.

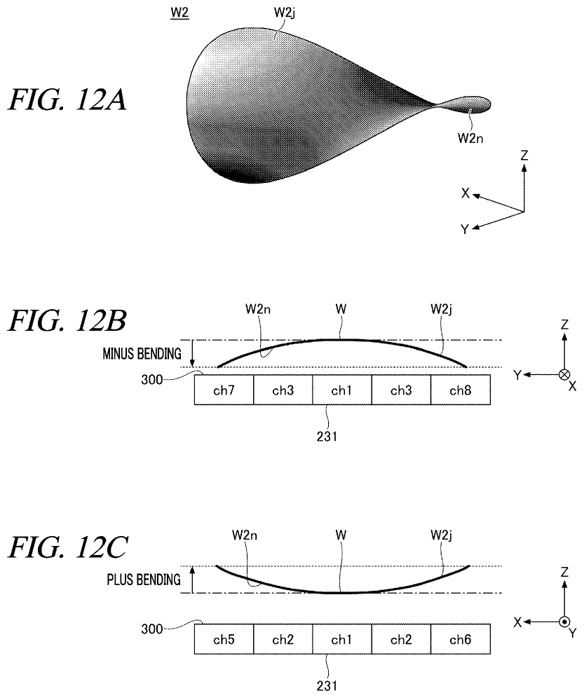

Now, referring to FIG. 12A to FIG. 12C, the bending of the lower wafer W2 will be described. In FIG. 12A, black and white gradation indicate the height of the top surface (bonding surface W2j) of the lower wafer W2 with respect to the attraction surface 300 of the lower chuck 231. The closer the color is to black, the lower the height of the top surface of the lower wafer W2, and the smaller the gap between the top surface of the lower wafer W2 and the attraction surface 300 of the lower chuck 231.

The bending of the lower wafer W2 is measured by, for example, a bending measuring device 5 (see FIG. 1) provided separately from the bonding apparatus 1, and the control device 90 acquires information on the state of the bending of the lower wafer W2 measured by the bending measuring device 5. In addition, the bending measuring device 5 may be provided as a part of the bonding apparatus 1. Alternatively, the bonding apparatus 1 may be configured to measure the bending by non-illustrated multiple displacement meters provided in the bonding module 41 when the upper wafer W1 or the lower wafer W2 is carried in.

Before the attracting pressure is generated in the attraction surface 300 of the lower chuck 231 by the attracting pressure generator 310 (see FIG. 11), the lower wafer W2 may be bent as shown in FIG. 12A. By way of example, the bending of the lower wafer W2 occurs when a plurality of films are stacked on a semiconductor substrate such as a silicon wafer. Each film is formed by a CVD (Chemical Vapor Deposition) method, an ALD (Atomic Layer Deposition) method, a spin-on method, or the like. During the formation of the films, a stress is applied to the lower wafer W2 due to a difference in thermal expansion, causing the lower wafer W2 to be bent.

In most cases, the lower wafer W2 may be bent symmetrically with two orthogonal diametrical straight lines in between, that is, line-symmetrically. This is because the Young's modulus, Poisson's ratio, and shear elastic coefficient of the semiconductor substrate such as the silicon wafer change in a cycle of 90°. The two orthogonal diametrical straight lines extend in a specific crystal orientation of the semiconductor substrate when viewed in a direction (Z-axis direction) orthogonal to the attraction surface 300.

In the bonding apparatus 1, the lower wafer W2 is delivered from the transfer device 61 to the lower chuck 231 so that its two orthogonal diametric straight lines are aligned with the X-axis direction and the Y-axis direction of the lower chuck 231, respectively. For example, the direction (posture) of the lower wafer W2 is adjusted by the second position adjusting device 52 (see FIG. 2) mentioned above.

The bending of the lower wafer W2 has two forms: a form in which the lower wafer W2 is bent in a direction (vertically downward direction) allowing outer peripheries of the lower wafer W2 at symmetrical positions to approach the attraction surface 300 with respect to the center of the lower wafer W2, and a form in which the lower wafer W2 is bent in a direction (vertically upward direction) allowing the outer peripheries at the symmetrical positions to be moved away from the attraction surface 300. Hereinafter, the bending of the lower wafer W2 in which the outer peripheries of the lower wafer W2 face downwards is called minus (−) bending (first form), and the bending of the lower wafer W2 in which the outer peripheries of the lower wafer W2 face upwards is called plus (+) bending (second form).

Here, a disc-shaped member such as the lower wafer W2 has a saddle-shaped curved surface that is curved in a concave shape from the two outer peripheries toward the center on the X-axis when the lower wafer W2 is curved in a convex shape toward the center from the two outer peripheries on the Y-axis which is offset from the X-axis by 90°. Therefore, the bending of the lower wafer W2 is in the opposite directions in the two orthogonal diametric straight lines. That is, when the minus bending occurs at the outer peripheries in the Y-axis direction, as shown in FIG. 12B, the plus bending occurs at the outer peripheries in the X-axis direction, as shown in FIG. 12C.

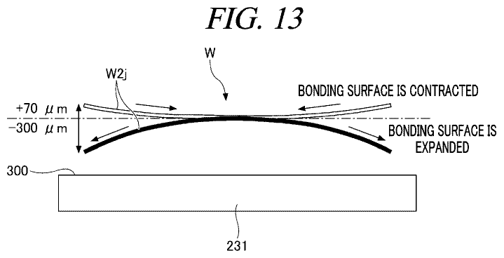

Now, an effect of the bending of the lower wafer W2 on the bonding surface W2j will be explained with reference to FIG. 13. In FIG. 13, for ease of understanding, a cross section of the lower wafer W2 in the Y-axis direction is illustrated in black, and a cross section of the lower wafer W2 in the X-axis direction is illustrated in white, and the two are superimposed.

The bonding surface W2j, which is the top surface of the lower wafer W2, expands and contracts along with the bending that occurs throughout the lower wafer W2. In a cross section along a diametrical direction (Y-axis direction in FIG. 13) in which the minus bending occurs, the bonding surface W2j expands because a pair of its outer peripheries is lowered vertically downwards with respect to its center. Meanwhile, in a cross section along a diametrical direction (X-axis direction in FIG. 13) in which the plus bending occurs, the bonding surface W2j contracts because the pair of its outer peripheries are raised vertically upwards with respect to its center.

However, as for the expansion and contraction that occurs in the bonding surface W2j, the amount of the bending of the outer peripheries with respect to the center in the X-axis direction may be different from the amount of the bending of the outer peripheries with respect to the center in the Y-axis direction. By way of example, as shown in FIG. 13, when the amount of the minus bending in the Y-axis direction is −300 μm and the amount of the plus bending in the X-axis direction is +70 μm, it can be said that the bonding surface W2j is greatly expanded in the Y-axis direction while being slightly contracted in the X-axis direction.

In this way, when the influence of the expansion is large in the bonding surface W2j, the lower chuck 231 improves a distribution of the residual stress of the lower wafer W2 by attracting the lower wafer W2 so that the bonding surface W2j is contracted in the diametrical direction (Y-axis direction in FIG. 13) in which the expansion has occurred. Specifically, when attracting the lower wafer W2 by the lower chuck 231, the bonding apparatus 1 gradually attracts the lower wafer W2 from the outer periphery of the lower wafer W2 toward the center thereof. In this way, by first fixing the outer periphery of the lower wafer W2, the lower chuck 231 can guide the bonding surface W2j to be contracted toward the center of the lower wafer W2. Hereinafter, this attracting operation in the attraction surface 300 from the outer periphery of the lower wafer W2 toward the center thereof will be referred to as a periphery-to-center pattern.

On the other hand, when the influence of the contraction is large in the bonding surface W2j, the lower chuck 231 improves the distribution of the residual stress of the lower wafer W2 by attracting the lower wafer W2 so that the bonding surface W2j is expanded in the diametrical direction (X-axis direction in FIG. 13) where the contraction has occurred. Specifically, when attracting the lower wafer W2 by the lower chuck 231, the bonding apparatus 1 gradually attracts the lower wafer W2 from the center of the lower wafer W2 toward the outer periphery thereof. As a result, the lower chuck 231 first fixes the center of the lower wafer W2, and can guide the bonding surface W2j to be expanded toward the outer periphery of the lower wafer W2. Hereinafter, this attracting operation in the attraction surface 300 from the center of the lower wafer W2 toward the outer periphery thereof will be referred to as a center-to-periphery pattern.

The control device 90 of the bonding apparatus 1 selects the periphery-to-center pattern or the center-to-periphery pattern according to the state of the bending of the lower wafer W2 to thereby improve the distribution of the residual stress of the lower wafer W2 attracted on the attraction surface 300. By way of example, the control device 90 compares an absolute value of the bending in the X-axis direction and an absolute value of the bending in the Y-axis direction in the lower wafer W2, and selects the periphery-to-center pattern or the center-to-periphery pattern based on the form of the bending (minus bending or plus bending) having a larger absolute value. To attract the lower wafer W2, in the respective zones of the outer region C in the circumferential direction, outer first zones that first attract the lower wafer W2, and outer second zones that attract the lower wafer W2 later than the outer first zones are set. By way of example, as shown in FIG. 11, the zones ch7 and ch8 of the attraction surface 300 along the Y-axis direction are set as the outer first zones, and the zones ch5 and ch6 shifted by 90° from the outer first zones along the circumferential direction of the attraction surface 300 are set as the outer second zones. Alternatively, the zones ch5 and ch6 of the attraction surface 300 along the X-axis direction may be set as the outer first zones. In this case, the zones ch7 and ch8 that are shifted by 90° from the outer first zones along the circumferential direction of the attraction surface 300 may be set as the outer second zones.

In addition, the bonding apparatus 1 may set an intermediate first zone and an intermediate second zone in the respective zones of the intermediate region B. The intermediate first zone is a zone adjacent to the outer first zone. When the zones ch7 and ch8 are set as the outer first zones and the zones ch5 and ch6 are set as the outer second zones, the zone ch3 becomes the intermediate first zone, and the zone ch2 becomes the intermediate second zone. When the zones ch5 and ch6 are set as the outer first zones and the zones ch7 and ch8 are set as the outer second zones, the zone ch2 becomes the intermediate first zone, and the zone ch3 becomes the intermediate second zone.

Here, when attracting the lower wafer W2 by the lower chuck 231, the control device 90 may adjust the timing for the attracting operations in the respective zones on the lower wafer W2 in further detail, such as performing the center-to-periphery pattern after performing the periphery-to-center pattern first. This makes it possible to further disperse the residual stress of the lower wafer W2. Hereinafter, the operation of attracting the lower wafer W2 by the lower chuck 231 will be described in detail.

First, a description will be provided for a case where the minus bending occurs along the Y-axis direction, the plus bending occurs along the X-axis direction, and the absolute value of the amount of the bending in the Y-axis direction is larger than the absolute value of the amount of the bending in the X-axis direction, as shown in FIG. 13. In this case, the bonding surface W2j of the lower wafer W2 is mainly expanded along the Y-axis direction as stated above. Therefore, the control device 90 determines to first perform the periphery-to-center pattern in the Y-axis direction. Further, in view of the fact that the plus bending occurs along the X-axis direction, the control device 90 also makes a determination that the center-to-periphery pattern in the X-axis direction is to be performed after the periphery-to-center pattern in the Y-axis direction.

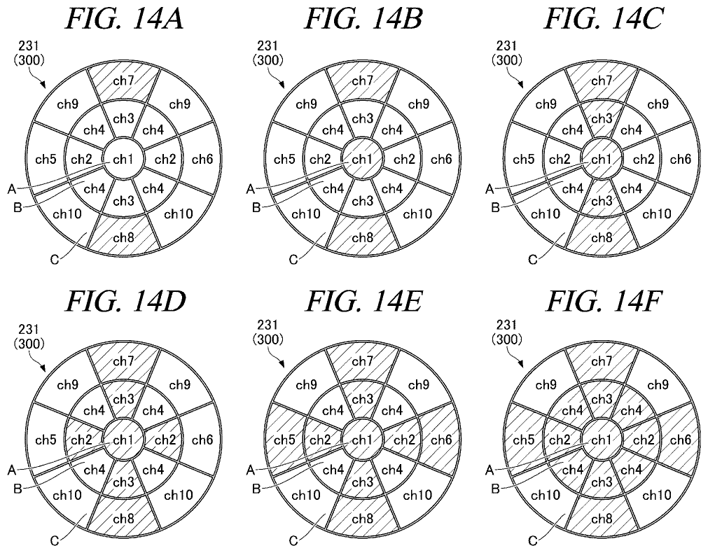

Then, when attracting the lower wafer W2 by lowering the plurality of holding pins 265, the control device 90 generates the attracting pressure according to the order of the attracting operations of the set channels, as shown in FIG. 14A to FIG. 14F. In FIG. 14A to FIG. 14F, the zones (channels) that generate the attracting pressure are indicated by hatching.

Specifically, as shown in FIG. 14A, the control device 90 first generates the attracting pressure in the zones ch7 and ch8, which are the zones of the outer region C in the Y-axis direction. Accordingly, the lower chuck 231 may first fix the outer periphery of the bonding surface W2j that is expanded in the Y-axis direction.

Next, as illustrated in FIG. 14B, the control device 90 generates the attracting pressure in the zone ch1, which is the zone at the center of the attraction surface 300 (central region A). Accordingly, when viewed on a cross section in the Y-axis direction, the periphery-to-center pattern is performed, in which the attracting pressure is generated from the outer periphery of the lower wafer W2 to the center thereof. As a result, the bonding surface W2j of the lower wafer W2 is fixed in a direction allowing it to be contracted in the Y-axis direction.

Thereafter, as shown in FIG. 14C, the control device 90 generates the attracting pressure in the two zones ch3 of the intermediate region B, which are adjacent to the zone ch1. Accordingly, it is possible to fix the lower wafer W2 along the Y-axis direction while suppressing the bonding surface W2j in the Y-axis direction from contracting too much toward the center, thus dispersing the residual stress of the lower wafer W2. Further, the control device 90 may be configured to generate the attracting pressure in the order of the zones ch7 and ch8→respective zones ch3→zone ch1 in the periphery-to-center pattern that is performed first.

Next, as shown in FIG. 14D, the control device 90 generates the attracting pressure in the two zones ch2 of the intermediate region B, which are adjacent to the zone ch1, in order to perform the center-to-periphery pattern in the X-axis direction. Also, as shown in FIG. 14E, the control device 90 generates the attracting pressure in the zones ch5 and ch6 of the outer region C, which are adjacent to the zones ch2, respectively. Accordingly, when viewed on a cross section in the X-axis direction, the center-to-periphery pattern is performed, in which the attracting pressure is generated from the center of the lower wafer W2 to the outer periphery thereof. As a result, the bonding surface W2j of the lower wafer W2 is fixed in a direction allowing it to be expanded in the X-axis direction. Alternatively, the control device 90 may be configured to generate the attracting pressure in the order of ch1 →ch5 and ch6→ch2 in the center-to-periphery pattern. Therefore, the bonding surface W2j in the X-axis direction can be suppressed from being expanded too much toward the outer periphery thereof, so that the residual stress can be dispersed around.

After the attraction in the X-axis direction and the Y-axis direction, the control device 90 performs attraction in a diagonal direction interposed therebetween, as illustrated in FIG. 14F. In this attraction in the diagonal direction, the control device 90 first generates the attracting pressure in the four zones ch4s, which are the zones of the intermediate region B.

Further, the control device 90 generates the attracting pressure in the two zones ch9 and the two zones ch10s, which are the zones of the outer region C (see FIG. 11). Thus, the lower chuck 231 can attract the lower wafer W2 by all the zones of the attraction surface 300 while expanding the lower wafer W2 in the diagonal direction. Further, as an example, when the expansion of the bonding surface W2j of the lower wafer W2 is large, the attracting pressure may be generated in the order of the outer region C (ch9 and ch10)→intermediate region B (ch4) in the diagonal direction as well.

As described above, the bonding apparatus 1 is capable of improving the distribution of the residual stress of the lower wafer W2 by performing the periphery-to-center pattern or the center-to-periphery pattern according to the state of the bending of the lower wafer W2. The above-described attracting operation is an example given for the case where the plus bending occurs in the X-axis direction, the minus bending occurs in the Y-axis direction, and the absolute value of the amount of the bending in the Y-axis direction is larger than the absolute value of the amount of the bending in the X-axis direction. The control device 90 performs another attracting operation for another state of the bending of the lower wafer W2.

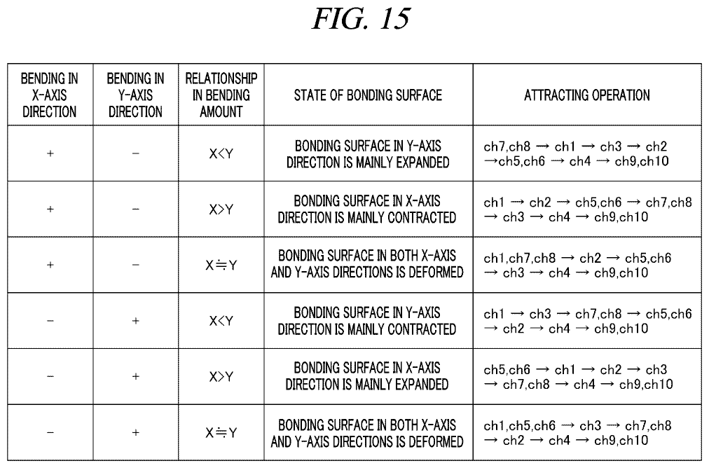

As an example, the control device 90 may select an attracting operation according to multiple conditions, as shown in a table of FIG. 15. In the table of FIG. 15, the topmost row (first row) shows an example of the state of bending of the lower wafer W2 and the attracting operation described in FIG. 13 and FIG. 14A to FIG. 14F.

The second row of the table in FIG. 15 shows a case where the plus bending occurs in the X-axis direction, the minus bending occurs in the Y-axis direction, and there is a relationship in the amounts of the bending that the absolute value of the amount of the bending in the X-axis direction is larger than the absolute value of the amount of the bending in the Y-axis direction. In this case, it can be said that the bonding surface W2j of the lower wafer W2 is mainly contracted in the X-axis direction. Therefore, the control device 90 determines to perform the center-to-periphery pattern in the X-axis direction. To this end, the attracting operation is performed to generate the attracting pressure in the order of ch1→ch2→ch5 and ch6 as the center-to-periphery pattern in the X-axis direction.

Thereafter, the control device 90 generates the attracting pressure in the order of ch7 and ch8→ch3 in the Y-axis direction, and also generates the attracting pressure in the order of ch4→ch9 and ch10 in the diagonal direction. This allows the bonding surface W2j to be guided to slightly contract in the Y-axis direction in which the minus bending has occurred. Alternatively, in the case where the absolute value of the amount of the bending in the Y-axis direction is small, the attracting pressure may be generated in the attracting operation as the center-to-periphery pattern in the order of ch1→ch3→ch7 and ch8 for the Y-axis direction as well after the center-to-periphery pattern in the X-axis direction.

The third row of the table in FIG. 15 presents a case where the plus bending occurs in the X-axis direction, the minus bending occurs in the Y-axis direction, and there is a relationship in the amounts of the bending that the absolute value of the amount of the bending in the X-axis direction is approximately equal to the absolute value of the amount of the bending in the Y-axis direction. That is, it can be said that the amount by which the bonding surface W2j of the lower wafer W2 contracts in the X-axis direction and the amount by which the bonding surface W2j expands in the Y-axis direction are approximately the same. In this case, the control device 90 generates the attracting pressure in the order of ch1, ch7 and ch8→ch2→ch5 and ch6→ch3→ch4→ch9 and ch10 in the attracting operation.

That is, the lower chuck 231 can first fix the Y-axis direction of the bonding surface W2j by simultaneously attracting the central region A and the outer region C in the Y-axis direction. Thereafter, the same as in the first row, the bonding surface W2j can be expanded in the X-axis direction by performing the center-to-periphery pattern in the X-axis direction.

The fourth row of the table in FIG. 15 shows a case where the minus bending occurs in the X-axis direction, the plus bending occurs in the Y-axis direction, and there is a relationship in the amounts of the bending that the absolute value of the amount of the bending in the X-axis direction is smaller than the absolute value of the amount of the bending in the Y-axis direction. In this case, it can be said that the bonding surface W2j of the lower wafer W2 is mainly contracted in the Y-axis direction. Therefore, the control device 90 determines to perform the center-to-periphery pattern in the Y-axis direction. To this end, in the attracting operation, the attracting pressure is generated in the order of ch1→ch3→ch7 and ch8 as the center-to-periphery pattern in the Y-axis direction.

Thereafter, the control device 90 generates the attracting pressure in the order of ch5 and ch6→ch2 in the X-axis direction, and also generates the attracting pressure in the order of ch4→ch9 and ch10 in the diagonal direction. In addition, when the absolute value of the bending in the X-axis direction is small, the attracting pressure may be generated in the order of ch1→ch2→ch5 and ch6 as the center-to-periphery pattern in the X-axis direction after the center-to-periphery pattern in the Y-axis direction.

The fifth row of the table in FIG. 15 shows a case where the minus bending occurs in the X-axis direction, the plus bending occurs in the Y-axis direction, and there is a relationship in the amounts of the bending that the absolute value of the amount of the bending in the X-axis direction is larger than the absolute value of the amount of the bending in the Y-axis direction. In this case, it can be said that the bonding surface W2j of the lower wafer W2 is mainly expanded in the X-axis direction. Therefore, the control device 90 determines to perform the periphery-to-center pattern in the X-axis direction. To this end, in the attracting operation, the attracting pressure is generated in the order of ch5 and ch6→ch1 as the periphery-to-center pattern in the X-axis direction. Thereafter, the control device 90 generates the attracting pressure in the zone ch2 of the X-axis direction. In addition, the control device 90 may generate the attracting pressure in the order of ch5 and ch6→ch2→ch1 in the X-axis direction, depending on the state of the bending of the lower wafer W2.

Further, the control device 90 generates the attracting pressure in the order of ch3→ch7 and ch8 in the Y-axis direction, and then generates the attracting pressure in the order of ch4→ch9 and ch10 in the diagonal direction. Alternatively, the control device 90 may generate the attracting pressure in the order of ch7 and ch8→ch3 when the absolute value of the amount of the bending in the Y-axis direction is large.

The sixth row of the table in FIG. 15 shows a case where the minus bending occurs in the X-axis direction, the plus bending occurs in the Y-axis direction, and there is a relationship in the amounts of the bending that the absolute value of the amount of the bending in the X-axis direction is approximately equal to the absolute value of the amount of the bending in the Y-axis direction. In this case, it can be said that the amount by which the bonding surface W2j of the lower wafer W2 expands in the X-axis direction and the amount by which the bonding surface W2j contracts in the Y-axis direction are approximately the same. Therefore, the control device 90 generates the attracting pressure in the order of ch1, ch5 and ch6→ch3→ch7 and ch8→ch2→ch4→ch9 and ch10 in the attracting operation.

That is, the lower chuck 231 can first fix the X-axis direction of the bonding surface W2j by attracting the central region A and the outer region C in the X-axis direction simultaneously. Thereafter, the same as in the fourth row, the center-to-periphery pattern may be performed in the Y-axis direction to thereby expand the bonding surface W2j in the Y-axis direction.

As described above, the substrate processing apparatus (bonding apparatus 1) can improve the distribution of the residual stress of the lower wafer W2 by selecting the periphery-to-center pattern or the center-to-periphery pattern according to the state of the bending of the lower wafer W2, thereby appropriately attracting the lower wafer W2. That is, when the bonding surface W2j is expanded, the attraction may be performed from the outer region C toward the central region A in the periphery-to-center pattern, thus making it possible to apply a stress in the direction in which the bonding surface W2j is contracted. Conversely, when the bonding surface W2j is contracted, the attraction may be performed from the central region A toward the outer region C in the center-to-periphery pattern, making it possible to apply a stress in the direction in which the bonding surface W2j is expanded.

In addition, when the bending occurs in orthogonal diametrical directions (X-axis direction and Y-axis direction) in the lower wafer W2, the bonding apparatus 1 can stably perform the periphery-to-center pattern and the center-to-periphery pattern by selecting the outer first zone and the outer second zone. In particular, the bonding apparatus 1 may compare the amount of the minus bending and the amount of the plus bending, and may perform the periphery-to-center pattern and the center-to-periphery pattern based on the form in which the absolute value of the amount of the bending is larger. As a result, the residual stress of the lower wafer W2 can be more reliably dispersed.

Further, by generating the attracting pressure in the direction from the central region A toward the outer region C after performing the periphery-to-center pattern, the bonding apparatus 1 can guide the bonding surface W2j to be smoothly expanded, thereby making it possible to improve the distribution of the residual stress of the lower wafer W2. In addition, by omitting the intermediate first zone in the periphery-to-center pattern, the bonding apparatus 1 can effectively relieve the stress around it. As a consequence, the residual stress can be further dispersed.

Besides, the substrate processing apparatus (bonding apparatus 1) according to the present disclosure is not limited to the above-described configuration, and can take various modification examples. For example, in the case where the bending of the lower wafer W2 occurs in the diagonal direction, the bonding apparatus 1 may first perform the attraction in the diagonal direction, and in this case as well, the periphery-to-center pattern and the center-to-periphery pattern can be appropriately selected.

Further, the bonding apparatus 1 selects the multiple attracting operations as shown in FIG. 15 by comparing the relationship between the absolute value of the minus bending amount of the lower wafer W2 and the absolute value of the plus bending amount of the lower wafer W2. However, the exemplary embodiment is not limited thereto. By way of example, in the lower wafer W2, the periphery-to-center pattern may be uniformly performed for the diametrical direction in which the minus bending occurs, and the center-to-periphery pattern may be uniformly performed for the diametrical direction in which the plus bending occurs.

Additionally, in the above-described exemplary embodiment, the attracting pressure for attracting the lower wafer W2 is set to be the same between the respective zones. However, the present exemplary embodiment is not limited thereto, and the attracting pressure may be set to different in the respective zones.

### Second Exemplary Embodiment

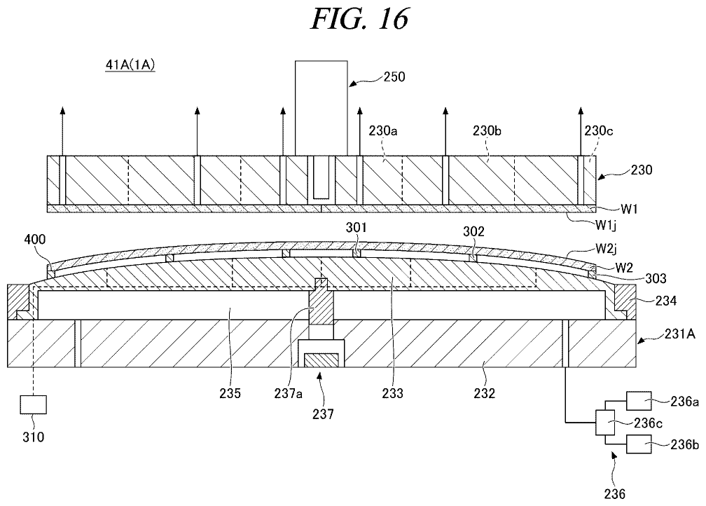

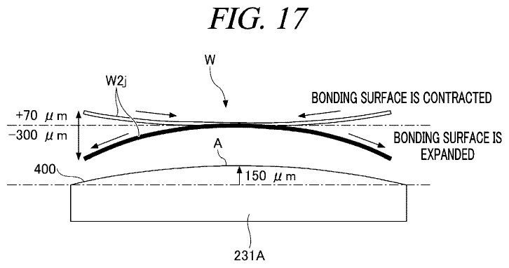

Now, a bonding module 41A according to a second exemplary embodiment will be described with reference to FIG. 16 and FIG. 17. The bonding module 41A is different from the bonding module 41A according to the first exemplary embodiment in that it is equipped with a lower chuck 231A forming a curved attraction surface 400.

The lower chuck 231A has, for example, a base member 232 and an attraction member 233. The attraction member 233 is provided above the base member 232, and is configured to attract and hold the lower wafer W2 from below. The attraction member 233 is formed in a circle shape with a diameter larger than the diameter of the lower wafer W2 when viewed from the top, and is fixed to the base member 232 via a fixing ring 234 provided on a peripheral portion thereof. A pressure-variable space 235 is formed between a top surface of the base member 232 and a bottom surface of the attraction member 233.

The same as in the first exemplary embodiment, annular ribs 301, 302, and 303 and ribs 305 having a radial pattern (see FIG. 11) are provided on a top surface of the attraction member 233. Due to the presence of these ribs 301, 302, 303, and 305, as illustrated in FIG. 11, the attraction surface 400 is given a central region A, an intermediate region B, and an outer region C, and, also, the intermediate region B and the outer region C are configured to have a plurality of zones in a circumferential direction. The plurality of zones are set as multiple channels ch1 to ch10 configured to attract the lower wafer W2 individually.

Further, the bonding module 41A is equipped with a second transforming device 236 configured to gently curve the lower wafer W2 by transforming the lower chuck 231A. The second transforming device 236 elastically transforms the attraction member 233 by changing a pressure in the pressure-variable space 235. The attraction member 233 is made of, by way of non-limiting example, ceramic such as alumina or silicon carbide. The second transforming device 236 is equipped with a vacuum pump 236a, a booster pump 236b, and a switching valve 236c.

The vacuum pump 236a decompresses the pressure-variable space 235 by discharging a gas from the pressure-variable space 235. As a result of decompressing the pressure-variable space 235, the top surface of the attraction member 233 becomes a horizontal plane. The booster pump 236b pressurizes the pressure-variable space 235 by supplying a gas into the pressure-variable space 235. As a result of pressurizing the pressure-variable space 235, the attraction surface 400 of the attraction member 233 becomes a curved surface in which the central region A protrudes. The protruding amount of the central region A of the attraction surface 400 can be adjusted by controlling the pressure of the pressure-variable space 235. The switching valve 236c performs a switchover between a state in which the pressure-variable space 235 is connected to the vacuum pump 236a and a state in which the pressure-variable space 235 is connected to the booster pump 236b.

The base member 232 has a measurer 237 configured to measure the protruding amount of the central region A of the attraction surface 400. A measurement target 237a of the measurer 237 is moved up and down along with a central portion of the attraction member 233. The measurer 237 is, by way of example, an electrostatic capacitance sensor, and is configured to measure the protruding amount by detecting electrostatic capacitance that varies according to the distance to the measurement target 237a.

The bonding module 41A configured as described above attracts the lower wafer W2 transferred by the transfer device 61 in the state that the attraction surface 400 of the lower chuck 231A is transformed as shown in FIG. 16. When attracting the lower wafer W2, the control device 90 appropriately performs the periphery-to-center pattern of attracting the lower wafer W2 from the periphery thereof and the center-to-periphery pattern of attracting the lower wafer W2 from the center thereof according to the state of bending of the lower wafer W2, as stated above.

In selecting the periphery-to-center pattern or the center-to-periphery pattern, the control device 90 makes a determination, taking into account the protruding amount of the central region A of the attraction surface 400 (curvature of the entire attraction surface 400) besides the state of bending of the lower wafer W2.

For example, as illustrated in FIG. 17, when the protruding amount of the attraction surface 400 of the lower chuck 231A is 150 μm and the outer periphery of the lower wafer W2 in the Y-axis direction has the minus bending of −300 μm, the curvature of the lower wafer W2 in the Y-axis direction becomes larger than the curvature of the attraction surface 400 in the Y-axis direction. In this case, the control device 90 selects the periphery-to-center pattern in which the attracting operation is performed from the outer periphery (ch7 and ch8: see FIG. 11) of the lower wafer W2 toward the center (ch1: see FIG. 11) thereof. This suppresses the expansion of the outer periphery of the lower wafer W2 in the Y-axis direction.

Meanwhile, when the protruding amount of the attraction surface 400 of the lower chuck 231A is 150 μm and the outer periphery of the lower wafer W2 in the Y-axis direction has the minus bending of −100 μm, the curvature of the lower wafer W2 in the Y-axis direction becomes smaller than the curvature of the attraction surface 400 in the Y-axis direction. In this case, even if the bonding surface W2j of the lower wafer W2 is expanded in the Y-axis direction, the amount of the expansion is small, compared to the state of the lower chuck 231A. Therefore, the control device 90 selects the center-to-periphery pattern in which the attracting operation is performed from the center (ch1: see FIG. 11) of the lower wafer W2 toward the outer periphery (ch7 and ch8: see FIG. 11) thereof. This enables the bonding surface W2j of the lower wafer W2 to be expanded in the Y-axis direction according to the curvature of the attraction surface 400.

In addition, when the outer periphery of the lower wafer W2 has the plus bending (for example, in the case of the X-axis direction in FIG. 17), the outer periphery of the lower wafer W2 is bent in an opposite direction to the curved surface of the attraction surface 400. Therefore, the control device 90 always selects the center-to-periphery pattern for the plus bending. As a result, the bonding module 41A can smoothly expand the bonding surface W2j for the plus bending of the lower wafer W2.

As described above, in the bonding module 41A according to the second exemplary embodiment, by selecting the periphery-to-center pattern or the center-to-periphery pattern to attract the lower wafer W2, the distribution of the residual stress of the lower wafer W2 can be improved. In particular, in the bonding module 41, since the attraction surface 400 is formed as the curved surface, a difference in expansion rate between the upper wafer W1 and the lower wafer W2 can be reduced when they are bonded, so that misalignment between the upper wafer W1 and the lower wafer W2 after being bonded can be reduced.

It should be noted that the substrate processing apparatus and the substrate placing method according to the exemplary embodiments are illustrative in all respects and are not anyway limiting. The above-described exemplary embodiments can be modified and improved in various ways without departing from the scope and the spirit of claims. Unless contradictory, other configurations may be adopted, and the disclosures in the various exemplary embodiments can be combined appropriately.

This application claims priority to Japanese Patent Application No. 2022-135106, filed on Aug. 26, 2022, which application is hereby incorporated by reference in their entirety.

### EXPLANATION OF CODES

1: Bonding apparatus (substrate processing apparatus)
90: Control device (controller)
231, 231A: Lower chuck (holder)
300, 400: Attraction surface
310: Attracting pressure generator
A: Central region
C: Outer region
W2: Lower wafer

1. A substrate processing apparatus, comprising:
a holder having an attraction surface configured to attract a substrate, the attraction surface having a circular central region and an annular outer region disposed outside the central region;
an attracting pressure generator configured to generate an attracting pressure individually in the central region, in an outer first zone set on a portion of the outer region in a circumferential direction, and in an outer second zone set on a portion of the outer region in the circumferential direction, the outer second zone being different from the outer first zone; and
circuitry configured to
control the attracting pressure generator,
select, based on a state of bending of the substrate, a periphery-to-center pattern in which the attracting pressure is generated in an order of the outer first zone and the central region, or a center-to-periphery pattern in which the attracting pressure is generated in an order of the central region and the outer first zone.

2. The substrate processing apparatus of claim 1, wherein
before the circuitry controls the attracting pressure generator to generate the attracting pressure in the attraction surface, the substrate has a first form in which the substrate is bent in a direction allowing an outer periphery of the substrate to approach the attraction surface with respect to a center of the substrate, or a second form in which the substrate is bent in a direction allowing the outer periphery of the substrate to be moved away from the attraction surface with respect to the center of the substrate,
the circuitry is further configured to execute the periphery-to-center pattern when the substrate has the first form in a first diametrical direction, and
the circuitry is further configured to execute the center-to-periphery pattern when the substrate has the second form in a second diametrical direction.

3. The substrate processing apparatus of claim 2, wherein
the first diametrical direction and the second diametrical direction are orthogonal to each other at the center of the substrate, and the outer first zone and the outer second zone are set at positions offset other by 90 degrees along the circumferential direction of the attraction surface.

4. The substrate processing apparatus of claim 3, wherein the circuitry is further configured to
compare a bending amount of the outer periphery with respect to the center of the substrate having the first form and a bending amount of the outer periphery with respect to the center of the substrate having the second form,
execute the periphery-to-center pattern when an absolute value of the bending amount of the first form is larger than an absolute value of the bending amount of the second form, and
execute the center-to-periphery pattern when the absolute value of the bending amount of the first form is smaller than the absolute value of the bending amount of the second form.

5. The substrate processing apparatus of claim 4, wherein the circuitry is configured to control the attracting pressure generator to generate the attracting pressure in an order of the central region and the outer second zone in the second diametrical direction after executing the periphery-to-center pattern in the first diametrical direction.

6. The substrate processing apparatus of claim 1, wherein
the attraction surface has an annular intermediate region between the central region and the outer region,
the intermediate region has an intermediate first zone adjacent to the outer first zone, and an intermediate second zone adjacent to the outer second zone, and
the circuitry is configured to control the attracting pressure generator to generate the attracting pressure in an order of the central region, the intermediate first zone, and the outer first zone in the center-to-periphery pattern.

7. The substrate processing apparatus of claim 6, wherein the circuitry is further configured to
omit the intermediate first zone in the periphery-to-center pattern, and
control the attracting pressure generator to generate the attracting pressure in an order of the outer first zone and the central region.

8. The substrate processing apparatus of claim 1, wherein the attraction surface is formed as a curved surface with the central region protruding higher than the outer region.

9. The substrate processing apparatus of claim 8, wherein the circuitry is further configured to
compare, when the substrate is bent in the direction allowing the outer periphery of the substrate to become closer to the attraction surface with respect to the center of the substrate, a curvature of the substrate with a curvature of the attraction surface,
execute the periphery-to-center pattern when the curvature of the substrate is larger than the curvature of the attraction surface, and
execute the center-to-periphery pattern when the curvature of the substrate is smaller than the curvature of the attraction surface.

10. The substrate processing apparatus of claim 1, wherein the circuitry is further configured to
acquire measurement information of the bending of the substrate, and
select the periphery-to-center pattern or the center-to-periphery pattern based on the measurement information.

11. The substrate processing apparatus of claim 1, wherein the substrate processing apparatus is configured as a bonding apparatus configured to bond the substrate attracted by the holder and another substrate positioned to face the substrate.

12. The substrate processing apparatus of claim 11, wherein the holder is a lower chuck configured to attract and hold the substrate vertically under the another substrate.

13. A substrate processing method of performing a substrate processing while a substrate is attracted to an attraction surface of a holder, the substrate processing method comprising:
generating, by an attracting pressure generator, an attracting pressure individually in a circular central region, in an outer first zone, and in an outer second zone set on the attraction surface, the outer first zone being set on a portion of an annular outer region in a circumferential direction, the annular outer region being disposed outside the central region, and the outer second zone being set on a portion of the annular outer region in the circumferential direction, the outer second zone being different from the outer first zone; and
before the generating of the attracting pressure, selecting, based on a state of bending of the substrate, a periphery-to-center pattern in which the attracting pressure is generated in an order of the outer first zone and the central region, or a center-to-periphery pattern in which the attracting pressure is generated in an order of the central region and the outer first zone is selected, wherein
in the generating of the attracting pressure, the substrate is attracted to the attraction surface according to a sequence of the selected pattern.

14. The substrate processing method of claim 13, wherein
before the generating of the attracting pressure, the substrate has a first form in which the substrate is bent in a direction allowing an outer periphery of the substrate to approach the attraction surface with respect to a center of the substrate, or a second form in which the substrate is bent in a direction allowing the outer periphery of the substrate to be moved away from the attraction surface with respect to the center of the substrate, and
the substrate processing method further comprising:
performing the periphery-to-center pattern when the substrate has the first form in a first diametrical direction; and
performing the center-to-periphery pattern when the substrate has the second form in a second diametrical direction.

15. The substrate processing method of claim 14, wherein
the first diametrical direction and the second diametrical direction are orthogonal to each other at the center of the substrate, and
the outer first zone and the outer second zone are set at positions offset by 90 degrees along the circumferential direction of the attraction surface.

16. The substrate processing method of claim 15, further comprising:
comparing a bending amount of the outer periphery with respect to the center of the substrate having the first form and a bending amount of the outer periphery with respect to the center of the substrate having the second form, wherein
the periphery-to-center pattern is performed when an absolute value of the bending amount of the first form is larger than an absolute value of the bending amount of the second form, and
the center-to-periphery pattern is performed when the absolute value of the bending amount of the first form is smaller than the absolute value of the bending amount of the second form.

17. The substrate processing method of claim 13, wherein
the attraction surface has an annular intermediate region between the central region and the outer region,
the intermediate region has an intermediate first zone adjacent to the outer first zone, and an intermediate second zone adjacent to the outer second zone, and
the attracting pressure is generated in an order of the central region, the intermediate first zone, and the outer first zone in the center-to-periphery pattern.
